(19) United States
(12) Patent Application Publication
(10) Pub. No.: US 2023/0156997 A1
(43) Pub. Date: May 18, 2023

(54) MEMORY UNIT, SEMICONDUCTOR MODULE, DIMM MODULE, AND MANUFACTURING METHOD FOR SAME

(71) Applicant: UltraMemory Inc., Tokyo (JP)

(72) Inventors: Fumitake OKUTSU, Tokyo (JP); Takatoshi MASUDA, Tokyo (JP)

(21) Appl. No.: 17/916,725

(22) PCT Filed: Apr. 3, 2020
(86) PCT No.: PCT/JP2020/015403

§ 371 Date: Oct. 3, 2022

(51) Int. Cl. H10B 12/00; H10B 80/00; H01L 23/367

(52) U.S. Cl. CPC H10B 12/01; H10B 80/00; H01L 23/3672

(57) ABSTRACT

A memory unit having a plurality of memory chips comprises: the memory unit that has a plurality of memory chips that are stacked; and protruding terminals that are disposed protruding from a side surface along the stacking direction of the memory unit, wherein the protruding terminals have surfaces that are positioned in a direction orthogonal to the protrusion direction, and between said surfaces, the surface roughness of a surface facing one way is greater than the surface roughness of a surface facing the other way.

### TECHNICAL FIELD

The present invention relates to a memory unit, a semiconductor module, a DIMM module, and manufacturing methods thereof.

### BACKGROUND ART

A volatile memory (Random Access Memory: RAM) such as a Dynamic Random Access Memory (DRAM) has been known as a storage device. The DRAM is required to have a capacity large enough to accommodate improving performance of an arithmetic unit (hereinafter, referred to as a logic chip) and increasing amount of data. Efforts have been therefore made to achieve a capacity increase through memory (memory cell array, memory chip) miniaturization and planar cell expansion. However, such an approach to a capacity increase is reaching a limit because of, for example, the vulnerability to noise resulting from the miniaturization and an increase in die area.

In this view, a technology has been developed in recent years that achieves a capacity increase by stacking a plurality of planar memories to form a three-dimensional (3D) structure. For example, a semiconductor module has been proposed that is obtained by providing electrode terminals on a side surface of a stack of a plurality of integrated circuit chips when the integrated circuit chips are stacked and bonded together (see, for example, Patent Documents 1 to 3).

Patent Document 1: Japanese Unexamined Patent Application (Translation of PCT Application), Publication. No. H8-505267

Patent Document 2: Japanese Unexamined Patent Application, Publication No. 2008-130932

Patent Document 3: Japanese Unexamined Patent Application, Publication No. 2014-120612

### DISCLOSURE OF THE INVENTION

### Problems to be Solved by the Invention

According to Patent Document 1, etching is performed on one surface of a stack, and metalization is applied to exposed electrical leads thereon. Unlike processes for wafers, the process according to Patent Document 1 is not an established process because the stack is formed first, and then a semiconductor process is performed on a side surface of the stack. The process is therefore costly for preparing necessary equipment and maintaining processing accuracy.

According to Patent Documents 2 and 3, when a wafer is cut, side electrodes are formed on resulting cut surfaces. According to Patent Documents 2 and 3, the side electrodes are formed while singulation is performed on wafers one wafer at a time. The side electrode formation is therefore costly. Furthermore, it is difficult to make positions of the side electrodes consistent.

An object of the present invention is to provide a memory unit, a semiconductor module, a DIMM module, and manufacturing methods thereof that make it possible to form electrodes on a side surface of a stack while containing costs.

### Means for Solving the Problems

The present invention is directed to a memory unit having a plurality of memory chips, the memory unit including: the plurality of memory chips put in a stack; and a protruding terminal disposed in the memory unit and protruding from a side surface thereof along a stacking direction, wherein one of opposite-facing surfaces of the protruding terminal in a direction intersecting with a protruding direction thereof has a greater surface roughness than the other.

Preferably, the protruding terminal includes: a plurality of base parts that are embedded in the memory unit and that protrude from the memory unit; and a coupling part that extends in the stacking direction while being exposed from the side surface of the memory unit and that couples the base parts, wherein one of opposite-facing surfaces of the coupling part in a direction intersecting with a protruding direction of the base parts has a greater surface roughness than the other.

Preferably, one of opposite-facing surfaces of the protruding terminal in a direction along the stacking direction has a greater surface roughness than the other.

The present invention is also directed to a semiconductor module having a plurality of memory chips, the semiconductor module including: a memory substrate having a power terminal exposed on one surface thereof, which is a placement surface; and at least one memory unit placed over the placement surface of the memory substrate, the at least one memory unit being the memory unit described above, wherein the protruding terminal protrudes from one end surface in the stacking direction and is connected to the power terminal.

Preferably, the semiconductor module includes a pair of the memory units located adjacent to each other and further includes an adhesive layer located adjacent to the protruding terminal in each of the memory units.

Preferably, the semiconductor module further includes a connecting part disposed between the power terminal and one end of the protruding terminal in the protruding direction of the protruding terminal, the connecting part electrically connecting the protruding terminal and the power terminal.

Preferably, the memory substrate has a communication circuit, and the memory chips have, at one end thereof adjacent to the memory substrate, a communication part configured to communicate with the communication circuit.

The present invention is also directed to a semiconductor module having a plurality of memory chips, the semiconductor module including: the memory unit described above; and a power supply plate connected to the protruding terminal, wherein the memory substrate over which the memory unit is placed has a communication circuit, the memory chips have a communication part configured to communicate with the communication circuit, and the protruding terminal is disposed on a side surface that is different from a surface where the communication part is disposed.

Preferably, the semiconductor module further includes a mount part through which the memory unit is mounted to the placement surface of the memory substrate, the mount part being placed on a portion of the placement surface of the memory substrate that is opposed to the memory unit and being not placed on a portion that is opposed to the protruding terminal.

The present invention is also directed to a semiconductor module having a plurality of memory chips, the semiconductor module including: a memory substrate having a communication circuit and a power terminal exposed on one surface thereof, which is a placement surface; at least one memory unit placed over the placement surface of the memory substrate, the at least one memory unit including the plurality of memory chips put in a stack; and power supply plates opposed and disposed on exposed surfaces of the memory unit and electrically connected to the power terminal, wherein the memory substrate has a communication circuit, the memory chips have, at one end thereof adjacent to the memory substrate, a communication part configured to communicate with the communication circuit in a contactless manner, and the memory chips have a protruding terminal protruding from a surface that is not opposed to the placement surface of the memory substrate and that is different from surfaces facing in the stacking direction.

The present invention is also directed to a DIMM module including: a plurality of the semiconductor modules described above; and a DIMM board having the plurality of semiconductor modules arranged over at least one surface thereof, which is an arrangement surface.

The present invention is also directed to a DIMM module including: a plurality of the semiconductor modules described above; a DIMM board having the plurality of semiconductor modules arranged over at least one surface thereof, which is an arrangement surface; and a heat spreader placed across all of the memory units in the plurality of semiconductor modules, and in contact with either or both of the memory units and adhesive layers.

The present invention is also directed to a method for manufacturing a memory unit having a plurality of memory chips, the method including: a memory unit formation step of forming memory units by stacking memory wafers having the plurality of memory chips, a scribe area, and protruding terminals that span the memory chips and the scribe area; and a singulation step of performing etching on the scribe area, except for the protruding terminals therein, thereby dividing the memory wafers into the individual memory units and exposing the protruding terminals.

Preferably, the method for manufacturing a memory unit further includes a bending step of bending the protruding terminals after the singulation step.

Preferably, the method for manufacturing a memory unit further includes: a memory unit placement step of placing the memory chips with an end of the protruding terminal in an in-plane direction opposed to a power terminal; and a connection step of electrically connecting the memory unit to a memory substrate.

Preferably, the method for manufacturing a memory unit further includes: a memory unit placement step of placing the memory chips; and a power supply plate connection step of connecting an end of the protruding terminal in an in-plane direction to a power supply plate, wherein in the memory unit placement step, the memory unit is opposed to and disposed on a memory substrate.

Preferably, the method for manufacturing a memory unit further includes: an adhesive layer formation step of forming, before the memory unit placement step, an adhesive layer on one stacking direction-facing surface of the protruding terminal in one of the memory units for bonding another memory unit; and a bonding step of bonding the two memory units using the adhesive layer before the memory unit placement step and after the adhesive layer formation step.

Preferably, the method for manufacturing a memory unit further includes a singulation step of dividing the memory wafers into the individual memory units before the adhesive layer formation step and after the memory unit formation step.

The present invention is also directed to a method for manufacturing a DIMM module, including: the method for manufacturing a semiconductor module described above; and an arrangement step of arranging, on at least one surface of a DIMM board, a plurality of the semiconductor modules manufactured, the at least one surface being an arrangement surface.

The present invention is also directed to a method for manufacturing a DIMM module, including: the method for manufacturing a semiconductor module described above; an arrangement step of arranging, on at least one surface of a DIMM board, a plurality of the semiconductor modules manufactured, the at least one surface being an arrangement surface; and a heat spreader placing step of placing a heat spreader across all of the memory units in the plurality of semiconductor modules, and in contact with either or both of the memory units and adhesive layers.

### Effects of the Invention

According to the present invention, it is possible to provide a memory unit, a semiconductor module, a DIMM module, and manufacturing methods thereof that make it possible to form electrodes on a side surface of a stack while containing costs.

### BRIEF DESCRIPTION OF THE DRAWINGS

FIG. 1 is a perspective view of a semiconductor module according to a first embodiment of the present invention;

FIG. 2 is a cross-sectional view taken along line A-A in FIG. 1;

FIG. 3 is a schematic diagram illustrating a step of manufacturing a memory unit according to the first embodiment;

FIG. 4 is a schematic diagram illustrating a step of manufacturing a semiconductor module according to the first embodiment;

FIG. 5 is a schematic diagram illustrating a step of manufacturing the semiconductor module according to the first embodiment;

FIG. 6 is a schematic diagram illustrating a step of manufacturing the semiconductor module according to the first embodiment;

FIG. 7 is a perspective view of a semiconductor module according to a second embodiment of the present invention;

FIG. 8 is a cross-sectional view taken along line B-B in FIG. 7;

FIG. 9 is a schematic diagram illustrating a step of manufacturing a memory unit according to a third embodiment of the present invention;

FIG. 10 is a schematic diagram illustrating a step of manufacturing a memory unit according to a fourth embodiment of the present invention;

FIG. 11 is a schematic cross-sectional view of a semiconductor module according to a fifth embodiment of the present invention;

FIG. 12 is a schematic cross-sectional view of a semiconductor module according to a sixth embodiment of the present invention;

FIG. 13 is a schematic cross-sectional view of a semiconductor module according to a seventh embodiment of the present invention;

FIG. 14 is a schematic perspective view of the semiconductor module according to the seventh embodiment;

FIG. 15 is a side view of a memory unit according to an eighth embodiment of the present invention;

FIG. 16 is a perspective view of a DIMM module according to a ninth embodiment of the present invention;

FIG. 17 is a perspective view of the DIMM module according to the ninth embodiment with a heat spreader disposed therein;

FIG. 18 is a perspective view of a semiconductor module according to a modification example of the present invention;

FIG. 19 is a perspective view of a memory module according to a modification example of the present invention;

FIG. 20 is a schematic cross-sectional view of a semiconductor module according to a modification example of the present invention; and

FIG. 21 is a schematic cross-sectional view of a semiconductor module according to a modification example of the present invention.

### PREFERRED MODE FOR CARRYING OUT THE INVENTION

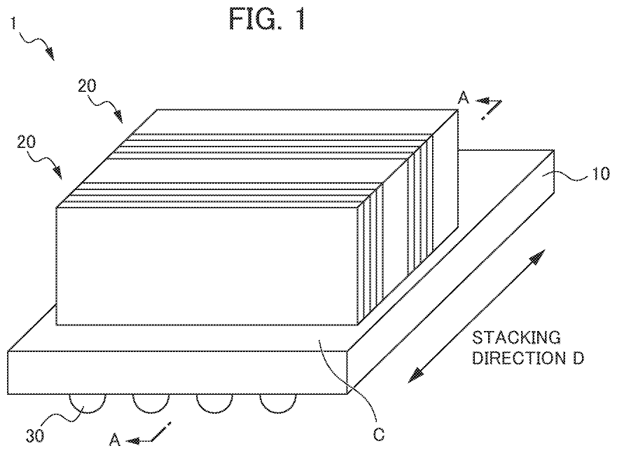

The following describes a memory unit 20, a semiconductor module 1, a DIMM module 100, and manufacturing methods thereof according to embodiments of the present invention with reference to FIGS. 1 to 16. The semiconductor module 1 according to each embodiment is, for example, a memory member having a plurality of memory chips 21 (for example, DRAM chips) put in a stack. The semiconductor module 1 has, for example, a configuration in which the stack of memory chips 21 is placed over a memory substrate 10. The semiconductor module 1 is designed to increase the number of memory chips 21 that are included therein by directing a stacking direction D of the memory chips 21 in an in-plane direction of the memory substrate 10. The memory unit 20 according to each embodiment has a terminal protruding from a side surface thereof, thereby facilitating the manufacture of the semiconductor module and containing costs.

### First Embodiment

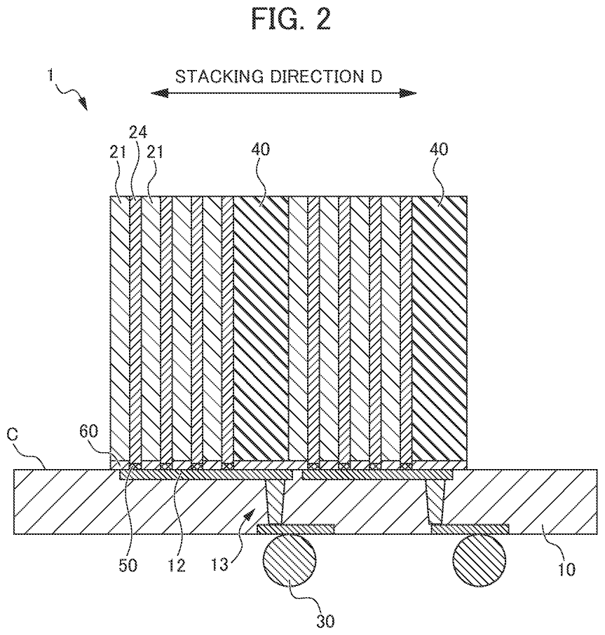

Next, a memory unit 20, a semiconductor module 1, a DIMM module 100, and manufacturing methods thereof according to a first embodiment of the present invention will be described with reference to FIGS. 1 to 6. The semiconductor module 1 according to the present embodiment is, for example, a DRAM module. As illustrated in FIGS. 1 and 2, the semiconductor module 1 has a plurality of memory chips 21. The semiconductor module 1 has a configuration in which the plurality of memory chips 21 are placed along the in-plane direction of the memory substrate 10. The semiconductor module 1 includes the memory substrate 10, memory units 20, adhesive layers 40, connecting parts 50, and a mount part 60. Each adhesive layer 40 may be, for example, obtained by coating both surfaces of a film-shaped base material (not shown) with an adhesive. The adhesive layer 40 may be a heat dissipation member for dissipating heat generated by the memory chips to the outside. The adhesive layer 40 may function as a spacer that adjusts a space between adjacent memory units 20, which are described below.

The memory substrate 10 is, for example, a silicon substrate. The memory substrate 10 is, for example, an active interposer. The memory substrate 10 includes conductive paths 13 that penetrate the memory substrate 10 in a thickness direction. In the present embodiment, the memory substrate 10 has power terminals 12 as part of the respective conductive paths 13. A portion of each power terminal 12 is exposed on one surface of the memory substrate 10, which is a placement surface C. The memory substrate 10 further has communication circuits (not shown) placed on the one surface thereof (for example, upper surface signal electrodes or non-contact communication circuits). In the present embodiment, the memory substrate 10 has upper surface signal electrodes or communication circuits capable of non-contact communication. The memory substrate 10 has, on an opposite surface thereof, bumps 30 that connect to the conductive paths 13 described above and that are electrically connectable to, for example, another substrate.

Each memory unit 20 includes a plurality of memory chips 21 put in a stack. At least one memory unit 20 is placed over the placement surface C of the memory substrate 10. According to the present embodiment, the semiconductor module 1 includes two memory units 20. Each memory unit 20 includes the memory chips 21 and protruding terminals 24.

Each memory chip 21 is a rectangular plate-like body in front view, and includes a memory circuit. The plurality of memory chips 21 are put in a stack. In this embodiment, each memory unit 20 includes a stack of four memory chips 21. The memory chips 21 are arranged so that the stacking direction D thereof is along the placement surface C.

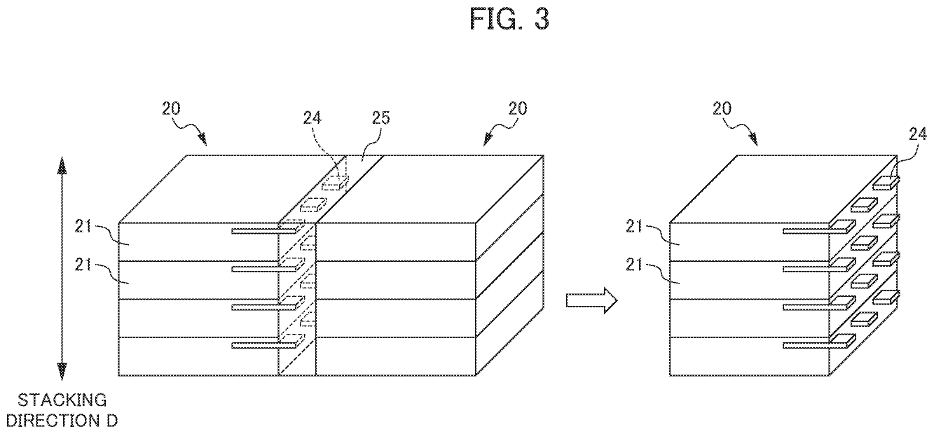

The protruding terminals 24 are made from a metal (for example, Cu, Au, or Al), and disposed in the memory unit 20 and protrude from one side surface thereof along the stacking direction D. The protruding terminals 24 are, for example, provided for each memory chip 21 as shown in FIG. 2. Two or more protruding terminals 24 are arranged in a direction intersecting with the stacking direction D of the memory chips 21 as shown in FIG. 3. One of opposite-facing surfaces of each protruding terminal 24 in a direction intersecting with a protruding direction thereof has a greater surface roughness than the other. In the present embodiment, one of opposite-facing surfaces of each protruding terminal 24 in a direction along the stacking direction D has a greater surface roughness than the other. In other words, of the surfaces of the protruding terminal 24, one surface that is exposed to etching described below has a greater surface roughness than the other surface that is not exposed to the etching. The protruding terminals 24 each function as an electrode terminal or a communication terminal for the corresponding memory chip 21. The surface roughness of the surface that is exposed to the etching is approximately 5 nm to 200 nm greater than the surface roughness of the surface that is not exposed to the etching.

Each. adhesive layer 40 is a rectangular plate-like body in front view. The adhesive layers 40 have the same or substantially the same size as the memory chips 21 in the stacking direction D. Each adhesive layer 40 is disposed between a pair of memory units 20 located adjacent to each other. The adhesive layer 40 is in contact with a memory chip 21 in at least one of the pair of memory units 20. The adhesive layer 40 thus bonds the pair of memory units 20 to each other. The adhesive layers 40 are formed using an insulating material. In the present embodiment, the adhesive layers 40 are formed from a material having relatively high thermal conductivity (for example, a base material such as beryllium oxide).

The connecting parts 50 are formed from a conductor such as a metal. The connecting parts 50 are, for example, microbumps. The connecting parts 50 are disposed in positions for connecting the power terminals 12 or the communication circuits (not shown) exposed on the placement surface C of the memory substrate 10 to ends of the protruding terminals 24. That is, the connecting parts 50 are provided in one-to-one correspondence with the protruding terminals 24 of each memory unit 20, and are disposed between the protruding terminals 24 and the power terminals 12 or the communication circuits.

The mount part 60 is disposed between the memory substrate 10 and the memory chips 21. The memory units 20 are mounted to the placement surface C of the memory substrate 10 through the mount part 60.

Next, operation of the semiconductor module 1 according to the present embodiment will be described. The memory substrate 10 supplies electric power to the connecting parts 50 through the bumps 30, and electrodes that penetrate the memory substrate 10 in the thickness direction, and the power terminals 12. The connecting parts 50 supply electric power to the protruding terminals 24 in the memory units 20. The protruding terminals 24 then each supply electric power to the corresponding memory chip 21.

Each memory chip 21 is configured to communicate with the memory substrate 10 through the protruding terminals 24, which are connected to the communication circuits using the connecting parts 50. That is, each memory chip 21 is configured to communicate with the memory substrate 10 without being affected by, for example, synchronization with the other memory chips 21.

Next, methods for manufacturing the memory unit 20 and the semiconductor module 1 according to the present embodiment will be described. The method for manufacturing the semiconductor module 1 according to the present embodiment includes a memory unit formation step, a singulation step, an adhesive layer formation step, a bonding step, a mount part placement step, a connecting part formation step, a memory unit placement step, and a connection step.

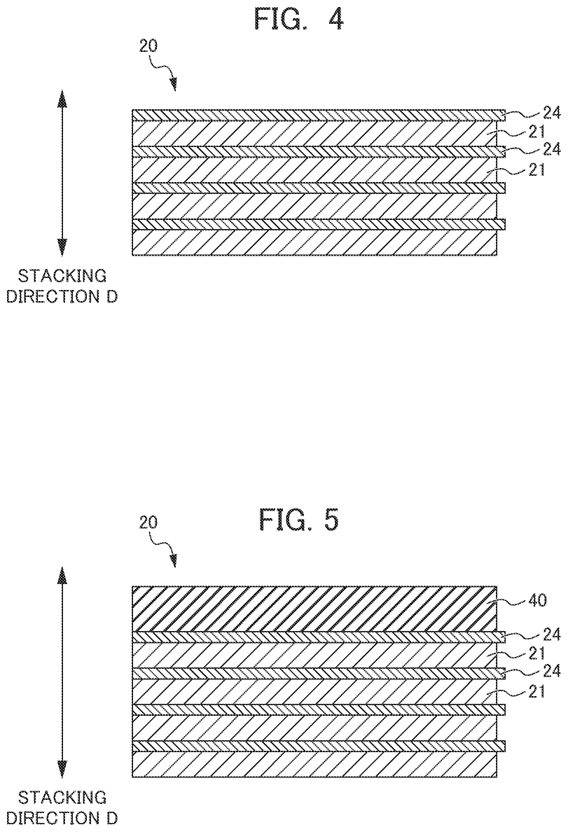

First, in the memory unit formation step, the memory units 20 are formed as shown in FIGS. 3 and 4. Specifically, in the memory unit formation step, a plurality of memory units 20 are formed by stacking memory wafers (not shown) having a plurality of memory chips 21 that are partitioned by a scribe area 25. Here, the memory wafers have the protruding terminals 24 that span the plurality of memory chips 21 and the scribe area 25. As a result of the memory unit formation step being performed, a stack of the memory wafers is formed in which the plurality of memory units 20 are connected in a direction intersecting with the stacking direction D. That is, a stack of the memory wafers is formed in which the plurality of memory units 20 are arranged side by side in a direction intersecting with the stacking direction D.

Next, the singulation step is performed. The singulation step is performed before the adhesive layer formation step and after the memory unit formation step. In the singulation step, etching is performed on the scribe area 25, except for the protruding terminals 24 therein, in the memory wafers having the plurality of memory units 20 arranged side by side, thereby dividing the memory wafers into the individual memory units 20. In the singulation step, for example, a protective film (photoresist or hard mask) (not shown) is applied to the positions of the memory chips 21, and then etching is performed on the scribe area 25 according to plasma dicing. As a result, the scribe area 25, except for the protruding terminals 24 therein, is removed. That is, in the singulation step, singulation is performed to divide the memory wafers into the individual memory units 20 with the protruding terminals 24 exposed while protruding from side surfaces intersecting with the stacking direction D. In the singulation step according to the present embodiment, the protruding terminals 24 are exposed on one side surface of each of the memory units 20 that intersects with the stacking direction D while protruding therefrom. It should be noted that the etching may be performed according to a method other than plasma dicing. For example, the etching may be performed according to dry etching such as plasma etching or according to a combination of wet etching and plasma dicing or dry etching. The etching method is not limited to plasma dicing as long as a process thereof causes the protruding terminals 24 to be exposed while protruding.

Next, the adhesive layer formation step is performed. In the adhesive layer formation step, as shown in FIG. 5, the adhesive layer 40 is formed on one stacking direction D-facing surface of each memory unit 20 (a protruding terminal 24 in the present embodiment) for bonding another memory unit 20.

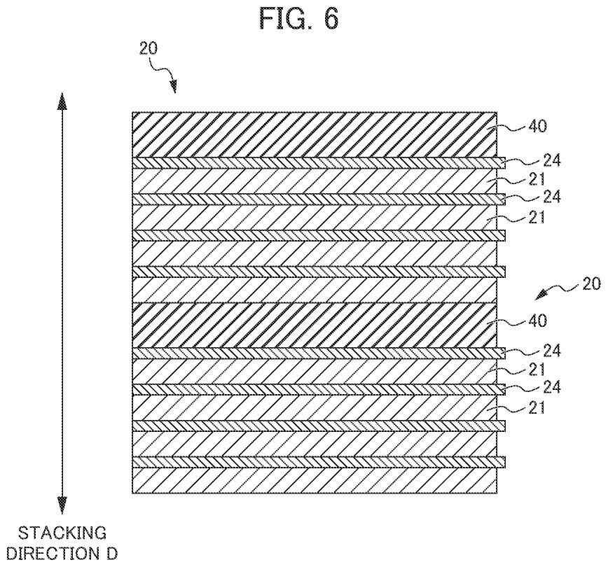

Next, the bonding step is performed. In the bonding step, two memory units 20 are bonded together using the adhesive layer 40 as shown in FIG. 6. The two memory units 20 are thus placed on one another in the stacking direction D.

Next, the mount part placement step is performed. In the mount part placement step, for example, a layer of mount part 60 is placed in a position that overlap the communication circuits (not shown) of the memory substrate 10 as shown in FIG. 2. In the mount part placement step, for example, the mount part 60 is placed on the placement surface C of the memory substrate 10, and on portions of the power terminals 12 and the communication circuits exposed on the placement surface C of the memory substrate 10, which specifically are portions that face the side surfaces of the memory units 20. That is, in the mount part placement step, the mount part 60 is placed on portions of the placement surface C of the memory substrate 10 that are opposed to the memory units 20 and is not placed on portions that are opposed to the protruding terminals 24.

Next, the connecting part formation step is performed. In the connecting part formation step, the connecting parts 50 are formed on portions of the power terminals 12 that are left exposed on the placement surface C of the memory substrate 10 as shown in FIG. 2.

Next, the memory unit placement step is performed. In the memory unit placement step, the memory units 20 are placed over the memory substrate 10 having the power terminals 12 and the communication circuits exposed on the one surface thereof, which is the placement surface C. In the memory unit placement step, portions of the protruding terminals 24 are opposed to and disposed on the power terminals 12. Furthermore, in the memory unit placement step, the other portions of the protruding terminals 24 are opposed to and disposed on the communication circuits.

Next, the connection step is performed. In the connection step, the memory units 20 are electrically connected to the memory substrate 10. Thereafter, the bumps 30, which are electrically connectable to, for example, another substrate, are formed on the opposite surface of the memory substrate 10. Through the above, the semiconductor module 1 such as shown in FIGS. 1 and 2 is formed.

The memory unit 20, the semiconductor module 1, and the manufacturing methods thereof according to the first embodiment described above produce the following effects.

(1) A memory unit 20 having a plurality of memory chips 21 includes: the plurality of memory chips 21 put in a stack; and a protruding terminal 24 disposed on the stack of the memory chips 21 and protruding from a side surface thereof along a stacking direction D. One of opposite-facing surfaces of the protruding terminal 24 in a direction intersecting with a protruding direction thereof has a greater surface roughness than the other. A semiconductor module having a plurality of memory chips 21 includes: a memory substrate 10 having a power terminal 12 exposed on one surface thereof, which as a placement surface C; and at least one memory unit 20 placed over the placement surface C of the memory substrate, the at least one memory unit 20 being the memory unit 20 described above. The protruding terminal 24 protrudes from one end surface in the stacking direction D and is connected to the power terminal 12. This configuration allows the protruding terminal 24 to be formed through simple singulation, reducing the manufacturing cost of the memory unit 20 and the semiconductor module 1.

(2) The semiconductor module 1 includes a pair of the memory units 20 located adjacent to each other, and further includes an adhesive layer 40 disposed between the memory units 20 and located adjacent to an electrode layer 23 in at least one of the memory units 20. This configuration allows the memory units 20 bonded to each other to be placed with the stacking direction D directed in the in-plane direction of the memory substrate 10. This configuration therefore further facilitates the mounting of the memory units 20 to the memory substrate 10. Furthermore, by using a material having high thermal conductivity for the adhesive layer 40, the adhesive layer 40 is expected to have an effect of a heat sink.

(3) The semiconductor module 1 further includes a connecting part 50 disposed between the power terminal 12 and one end of the protruding terminal 24 in the protruding direction of the protruding terminal 24, and the connecting part 50 electrically connects the protruding terminal 24 and the power terminal 12. This configuration provides an electrical connection between the memory substrate 10 and the protruding terminal 24, stabilizing the electric power supply from the memory substrate 10 to the memory units 20.

(4) The semiconductor module 1 further includes a mount part 60 through which the memory unit 20 is mounted to the placement surface C of the substrate. The mount part 60 is placed on a portion of the placement surface C of the memory substrate 10 that is opposed to the memory unit 20 and is not placed on a portion that is opposed to the protruding terminal 24. This configuration allows the side surfaces of the memory chips 21 to be mounted to the memory substrate 10, so that the memory unit 20 is attached to the memory substrate 10 in a stable manner.

(5) A method for manufacturing a memory unit 20 having a plurality of memory chips 21 includes: a memory unit formation step of forming memory units 20 by stacking memory wafers having the plurality of memory chips 21, a scribe area 25, and protruding terminals 24 that span the memory chips 21 and the scribe area 25; and a singulation step of performing etching on the scribe area 25, except for the protruding terminals 24 therein, thereby dividing the memory wafers into the individual memory units 20 and exposing the protruding terminals 24. This method allows the protruding terminals 24 to be exposed through etching. Therefore, the manufacturing cost is lower in the case of this method than in a case where a terminal is formed for each memory chip 21 and the memory chips 21 are put in a stack, or in a case where the terminals are formed after the memory chips 21 have been stacked.

(6) A method for manufacturing a semiconductor module 1 includes: a memory unit placement step of placing the memory chips 21 with an end of the protruding terminal 24 in the in-plane direction opposed to a power terminal 12; and a connection step of electrically connecting the memory unit 20 to a memory substrate 10. This method allows two memory units 20 to be easily connected. Thus, a plurality of memory units 20 that are placed over the memory substrate 10 can be easily formed.

(7) The method for manufacturing a semiconductor module 1 further includes: an adhesive layer formation step of forming, before the memory unit placement step, an adhesive layer 40 on one stacking direction D-facing surface of the protruding terminal 24 in one of the memory units 20 for bonding another memory unit 20; and a bonding step of bonding the two memory units 20 using the adhesive layer 40 before the memory unit placement step and after the adhesive layer formation step. This method makes it possible to easily obtain a plurality of memory units 20 bonded to each other.

### Second Embodiment

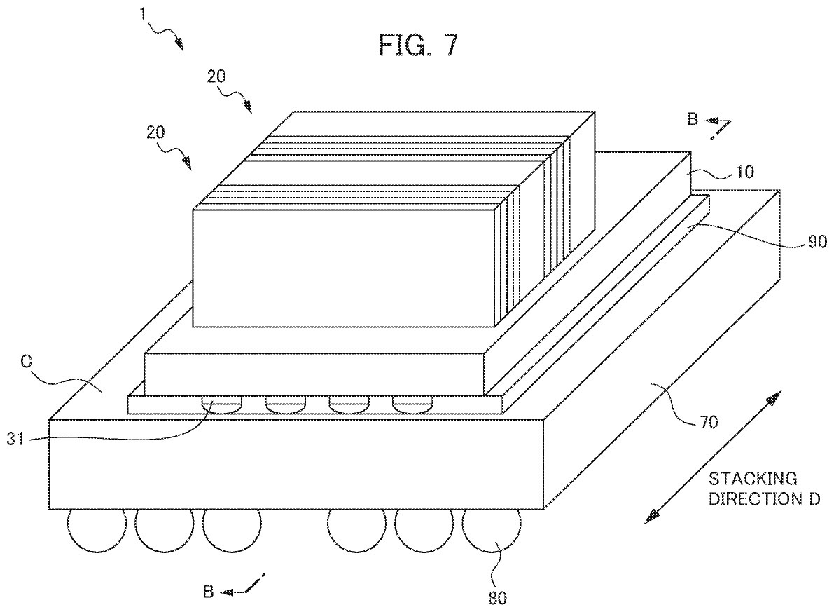

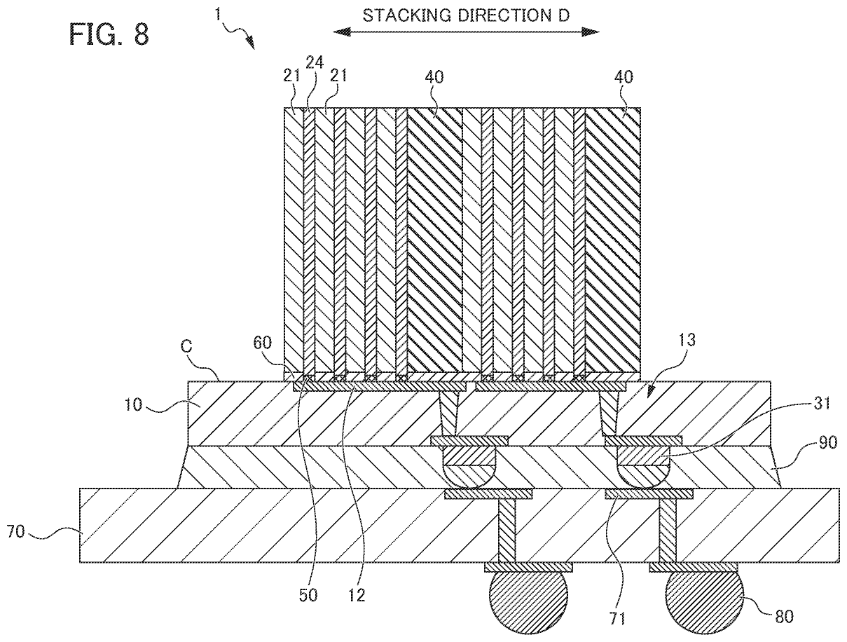

The following describes a memory unit 20, a semiconductor module 1, and manufacturing methods thereof according to a second embodiment of the present invention with reference to FIGS. 7 and 8. In the description of the second embodiment, the same elements of configuration as those of the foregoing embodiment are denoted by the same reference numerals, and description thereof will be omitted or simplified. The semiconductor module 1 according to the second embodiment differs from that according to the first embodiment in that the semiconductor module 1 according to the second embodiment further includes a package substrate 70 and a sealing part 90 as shown in FIGS. 7 and 8. The semiconductor module 1 according to the second embodiment further differs from that according to the first embodiment in that the memory substrate 10 of the second embodiment has pillars 31 instead of the bumps 30.

The package substrate 70 is, for example, a silicon substrate or an organic substrate. The package substrate 70 has a larger area than the memory substrate 10. The package substrate 70 has package electrodes 71 that penetrate the package substrate 70 in a thickness direction or that each form an electrical connection path. The package substrate 70 has one end surface opposed to the memory substrate 10 and an opposite end surface having solder balls 80 that are in contact with exposed portions of the package electrodes 71.

The sealing part 90 seals an interface between the memory substrate 10 and the package substrate 70. Specifically, the sealing part 90 seals the interface between the opposite surface of the memory substrate 10, which is opposite to the placement surface C, and the one end surface of the package substrate 70.

The pillars 31 are, for example, Cu pillars. An end of each pillar 31 is provided with, for example, solder for conductively connecting the power terminals 12 of the memory substrate 10 and the package electrodes 71 of the package substrate 70.

Next, a method for manufacturing the semiconductor module 1 according to the present embodiment will be described. The method according to the present embodiment includes forming the pillars 31 instead of the bumps 30 in the semiconductor module 1 manufactured according to the first embodiment. The pillars 31 are then aligned with the package electrodes 71 of the package substrate 70 and conductively connected to the package electrodes 71 through the solder provided on the ends of the pillars 31. This process is followed by the sealing with the sealing part 90. Through the above, the semiconductor module 1 according to the present embodiment is manufactured.

The semiconductor module 1 and the manufacturing method thereof according to the second embodiment described above produce the following effects.

(8) The semiconductor module 1 further includes a package substrate 70 and a sealing part 90. This configuration makes it possible to provide an easy-to-handle semiconductor module 1. For example, by adopting a layout conforming to the one provided by JEDEC Solid State Technology Association (JDEC) for the solder balls 80, it is possible to provide a highly versatile semiconductor module 1.

### Third Embodiment

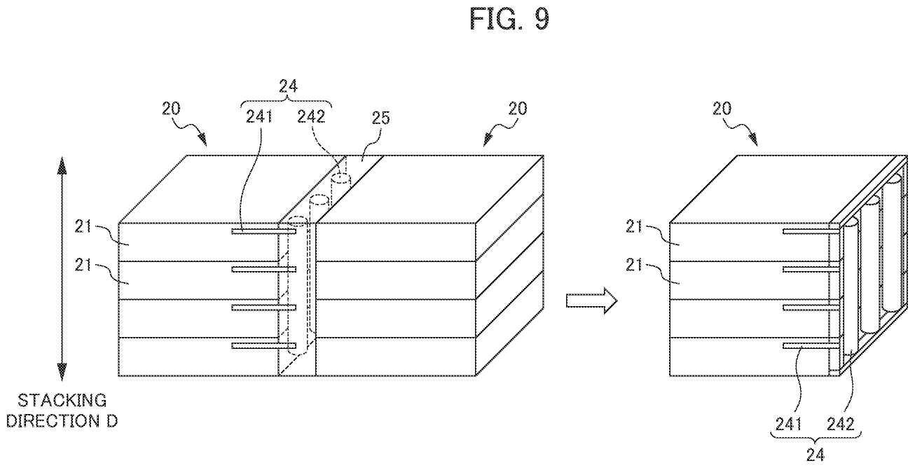

The following describes a memory unit 20, a semiconductor module 1, and manufacturing methods thereof according to a third embodiment of the present invention with reference to FIG. 9. In the description of the third embodiment, the same elements of configuration as those of the foregoing embodiments are denoted by the same reference numerals, and description thereof will be omitted or simplified. The memory unit 20 according to the third embodiment differs from those according to the first and second embodiments in that a protruding terminal 24 of the third embodiment includes base parts 241 and coupling parts 242 as shown in FIG. 9.

The base part 241 is provided with a plurality of base parts 241 as shown in FIG. 9. Each base part 241 according to the present embodiment has a rectangular flat plate-like shape in front view. The base parts 241 are embedded in the memory unit 20. The base parts 241 are, for example, embedded in one side of the memory unit 20 in a direction intersecting with the stacking direction D.

Each coupling part 242 is, for example, a cylindrical body. The base parts 241 extend in the stacking direction D, are exposed from a side surface of the memory unit 20, and couple the base parts 241. The coupling parts 242 are, for example, circular cylinders and couple the base parts 241 embedded in the one side of the memory unit 20. According to the present embodiment, three coupling parts 242 are arranged side by side in a direction intersecting with the stacking direction D. Furthermore, according to the present embodiment, one of opposite-facing surfaces of each coupling part 242 in a direction intersecting with a protruding direction of the base parts 241 has a greater surface roughness than the other.

Next, methods for manufacturing the memory unit 20 and the semiconductor module 1 according to the present embodiment will be described. The method for manufacturing the semiconductor module 1 further includes a coupling part formation step. Furthermore, the memory unit formation step according to the third embodiment differs from those according to the first and second embodiments in that the base parts 241 of the protruding terminal 24 do not extend to the scribe area 25.

The coupling part formation step is performed between the memory chip formation step and the singulation step. In the coupling part formation step, via holes (not shown) are formed along the stacking direction D to span the scribe area 25 and locations where the base parts 241 are formed. Then, each via hole is filled with an electrode (for example, Cu). In the coupling part formation step, the electrode inside each via hole formed in the scribe area 25 is left when the singulation is performed to obtain the individual memory units 20 by performing etching on the scribe area, forming the coupling parts 242.

The memory unit 20, the semiconductor module 1, and the manufacturing methods thereof according to the third embodiment described above produce the following effects.

(9) The protruding terminal 24 includes: a plurality of base parts 241 that are partially embedded in the memory chips 21 and that protrude from the memory unit 20; and coupling parts 242 that extend in the stacking direction D and that couple exposed portions of the base parts 241. One of opposite-facing surfaces of each coupling part 242 in a direction intersecting with the protruding direction of the base parts 241 has a greater surface roughness than the other. This configuration helps increase the area of contact between the protruding terminal 24 and The placement surface C of the substrate. As a result, it is possible to easily bond the memory chips 21 to the substrate.

### Fourth Embodiment

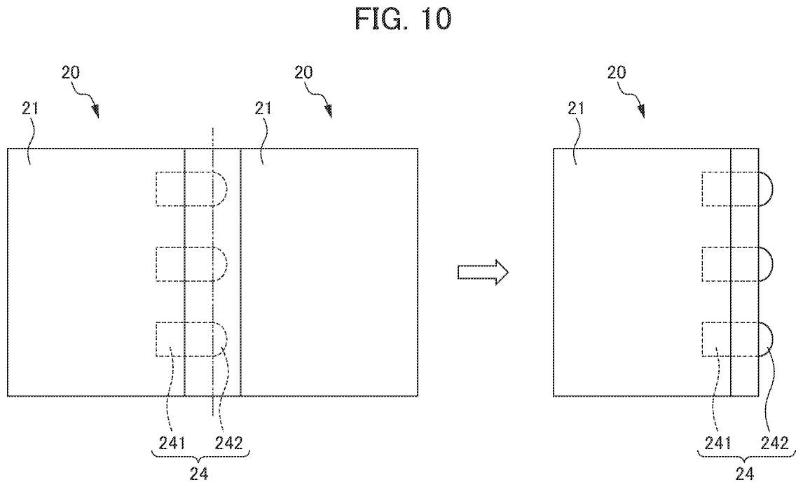

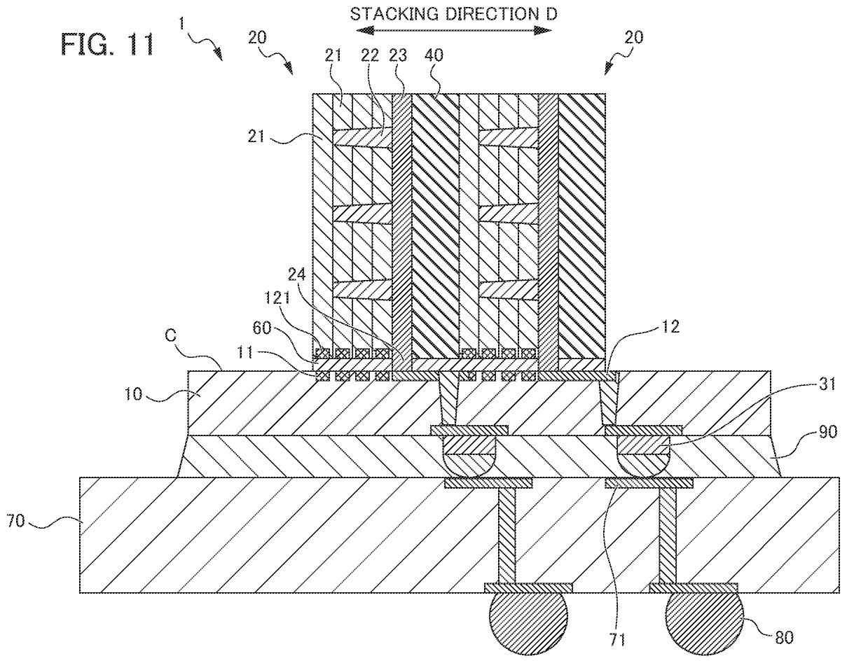

The following describes a memory unit 20, a semiconductor module 1, and manufacturing methods thereof according to a fourth embodiment of the present invention with reference to FIG. 10. FIG. 10 is a plan view of the memory unit 20 as seen in the stacking direction D. In the description of the fourth embodiment, the same elements of configuration as those of the foregoing embodiments are denoted by the same reference numerals, and description thereof will be omitted or simplified. A method for manufacturing the memory unit 20 according to the fourth embodiment differs from those according to the first to third embodiments in that stealth dicing is performed at the scribe area 25 as shown in FIG. 10 in a singulation step according to the fourth embodiment.

The stealth dicing in the singulation step modifies silicon in the scribe area 25. For example, along the scribe area 25, portions of the silicon that are located off the center of the via holes are modified in a perforated line pattern. The memory wafers are then expand-cut along the modified portions to split up into the individual memory units 20. In this case, as in the third embodiment, off-center sides of the via holes formed in the scribe area come off the electrodes in the via holes, forming the coupling parts 242. As described above, the portions to be modified are set appropriately so that the side surface protruding terminals do not come off during the expand-cutting. For example, portions located outward of the center of the circular cylinders are set to be modified.

The memory unit 20, the semiconductor module 1, and the manufacturing methods thereof according to the fourth embodiment described above produce the following effects.

(10) Stealth dicing is performed at the scribe area 25 in the singulation step. Such methods also make it possible to divide the memory wafers into the individual memory units 20 while leaving the protruding terminals 24.

### Fifth Embodiment

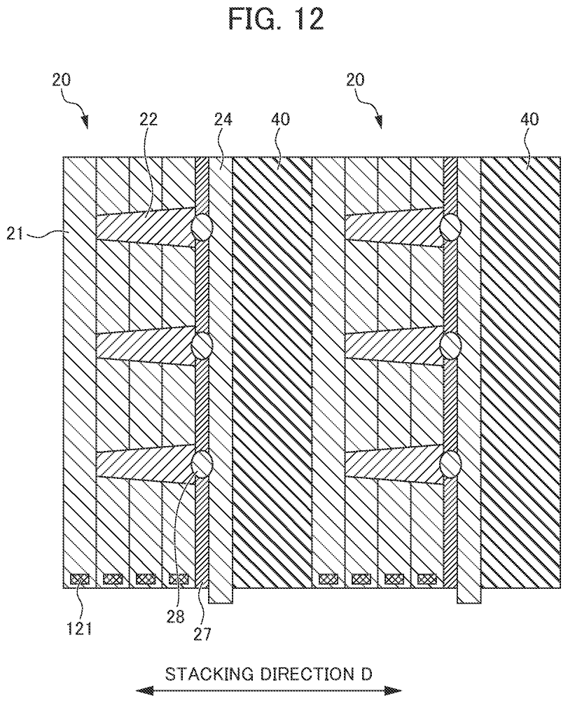

The following describes a memory unit 20, a semiconductor module 1, and manufacturing methods thereof according to a fifth embodiment of the present invention with reference to FIG. 11. In the description of the fifth embodiment, the same elements of configuration as those of the foregoing embodiments are denoted by the same reference numerals, and description thereof will be omitted or simplified. The memory unit 20 according to the fifth embodiment differs from those according to the first to fourth embodiments in that the memory unit 20 according to the fifth embodiment includes through electrodes 22 that penetrate some memory chips 21 as shown in FIG. 11. The memory unit 20 according to the fifth embodiment also differs from those according to the first to fourth embodiments in that the memory unit 20 according to the fifth embodiment includes communication parts 121. The semiconductor module 1 according to the fifth embodiment differs from those according to the first to fourth embodiments in that the semiconductor module 1 according to the fifth embodiment includes communication circuits 11. The memory unit 20 according to the fifth embodiment further differs from those according to the first to fourth embodiments in that the memory unit 20 according to the fifth embodiment includes a protruding terminal 24 formed using one end of an electrode layer 23 located at one end in the stacking direction D of the memory chips 21. The method for manufacturing the memory unit 20 according to the fifth embodiment differs from those according to the first to fourth embodiments in that the method according to the fifth embodiment includes further stacking the electrode layer 23 after the memory chips 21 have been stacked.

The through electrodes 22 are, for example, vias formed from a conductor such as a metal. The through electrodes 22 penetrate some memory chips 21 in the stacking direction D. Specifically, the through electrodes 22 penetrate, in the stacking direction D, memory chips 21 from the memory chip 21 located at one end to the memory chip 21 located adjacent to the memory chip 21 located at the other end. According to the present embodiment, a plurality of through electrodes 22 are provided and supply electric power to each memory chip 21.

The communication parts 121 (side surface signal electrodes (non-contact communication circuits)) are configured to communicate with the communication circuits 11 disposed on one surface of the memory substrate 10 in a contactless manner. Each of the communication parts 121 (side surface signal electrodes (non-contact communication circuits)) is located at one end of a corresponding one of the memory chips 21, which is an end adjacent to the memory substrate 10.

The electrode layer 23 is, for example, a plate-like body formed from a conductor such as a metal. The electrode layer 23 is stacked at one end surface in the stacking direction D, connected to the through electrodes 22, and also connected to a power terminal 12 through the protruding terminal 24, which is formed by the same formation method as in the first embodiment. Specifically, the electrode layer 23 is stacked on one end surface of the memory chip 21 located at the one end in the stacking direction D, and connected to the through electrodes 22 and the power terminal 12.

The memory unit 20, the semiconductor module 1, and the manufacturing methods thereof according to the fifth embodiment described above produce the following effects.

(11) The electrode layer 23 is disposed at the one end in the stacking direction D of the memory chips 21. By performing etching on the scribe area 25 after stacking the electrode layer 23 separately from the memory chips 21, the protruding terminal 24 that protrudes from a side surface of the stack of the memory chips 21 is obtained. Thus, it is possible to contain costs even if the protruding terminal 24 is placed after the memory chips 21 have been stacked.

### Sixth Embodiment

The following describes a memory unit 20, a semiconductor module, and manufacturing methods thereof according to a sixth embodiment of the present invention with reference to FIG. 12. In the description of the sixth embodiment, the same elements of configuration as those of the foregoing embodiments are denoted by the same reference numerals, and description thereof will be omitted or simplified. The memory unit 20 according to the sixth embodiment differs from that according to the fifth embodiment in that the memory unit 20 according to the sixth embodiment includes an adhesive layer 40 formed from an Si substrate and a layer of protruding terminal 24 formed on one surface of the adhesive layer 40 as shown in FIG. 12. Furthermore, the sixth embodiment differs from the fifth embodiment in that the protruding terminal 24 that protrudes from the adhesive layer 40 is formed when singulation is performed at the adhesive layer 40. Furthermore, the sixth embodiment differs from the fifth embodiment in that the protruding terminal 24 is bonded at one end surface of the memory unit 20 in the stacking direction D using a bonding layer 27 and connected to through electrodes 22 using microbumps 28.

The memory unit 20, the semiconductor module 1, and the manufacturing methods thereof according to the sixth embodiment described above produce the following effects.

(12) The protruding terminal 24 is formed on one surface of the adhesive layer 40. Forming the protruding terminal 24 by the above-described method also allows the protruding terminal 24 to be placed after the memory chips 21 have been stacked while containing costs.

### Seventh Embodiment

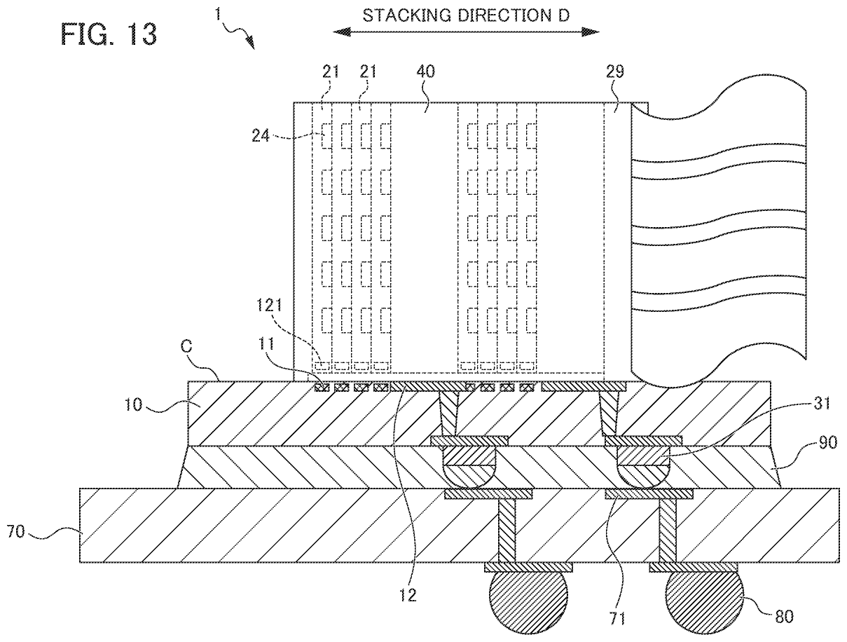

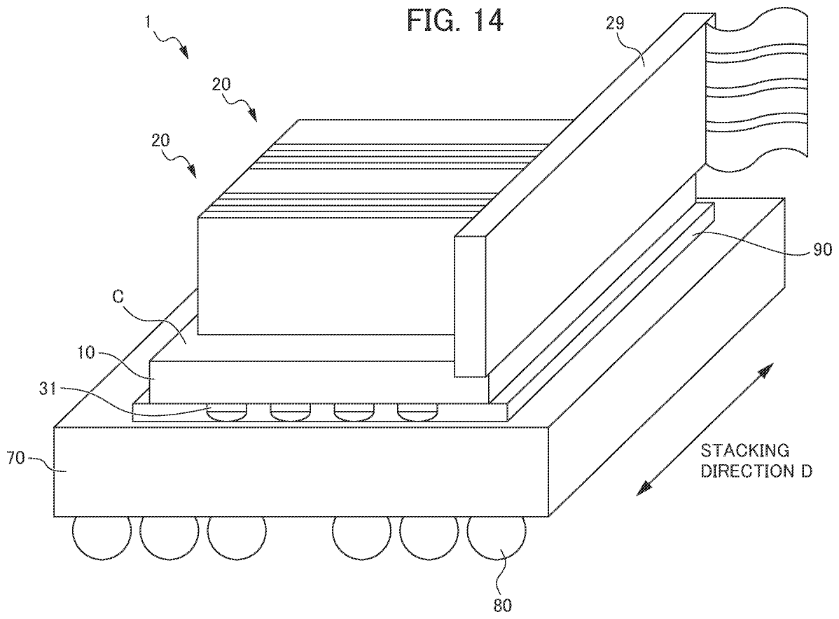

The following describes a memory unit 20, a semiconductor module 1, and manufacturing methods thereof according to a seventh embodiment of the present invention with reference to FIGS. 13 and 14. In the description of the seventh embodiment, the same elements of configuration as those of the foregoing embodiments are denoted by the same reference numerals, and description thereof will be omitted or simplified. The semiconductor module 1 according to the seventh embodiment differs from those according to the fifth and sixth embodiments in that protruding terminals 24 in the semiconductor module 1 according to the seventh embodiment are placed on surfaces that do not face the substrate 10 as shown in FIGS. 13 and 14. Furthermore, the semiconductor module 1 according to the seventh embodiment differs from those according to the fifth and sixth embodiments in that the semiconductor module 1 according to the seventh embodiment further includes a power supply plate 29 connected to the protruding terminals 24.

The protruding terminals 24 protrude from one of side surfaces of each memory unit 20 that is different from a surface where communication parts 121 are disposed. According to the present embodiment, the protruding terminals 24 are disposed on side surfaces of the memory chips 21 and arranged along one end of each memory chip 21 in the thickness direction. The protruding terminals 24 are arranged in lateral rows along the stacking direction D of the memory chips 21, and each row includes one protruding terminal 24 for each memory chip 21. It should be noted that the protruding terminals 24 may be disposed along one end in the thickness direction on an upper surface of each memory chip 21, which is a surface at an end opposite to an end where the corresponding communication part 121 is disposed. The memory unit 20 may include a protruding terminal 24 disposed at one end of the stack of memory chips 21 in the stacking direction D as shown in FIGS. 11 and 12.

The power supply plate 29 is a rectangular plate-like body in front view. The power supply plate 29 has, on one surface thereof, terminals corresponding to the positions of the protruding terminals 24. The power supply plate 29 is connected to an external power supply circuit (not shown).

The memory unit 20, the semiconductor module 1, and the manufacturing methods thereof according to the seventh embodiment described above produce the following effects.

(13) The semiconductor module 1 further includes the power supply plate 29 connected to the protruding terminals 24, and the protruding terminals 24 are disposed on a side surface that is different from a surface where the communication parts 121 are disposed. This configuration makes it possible to supply electric power to the memory unit 20 from an external source without depending on the substrate 10.

### Eighth Embodiment

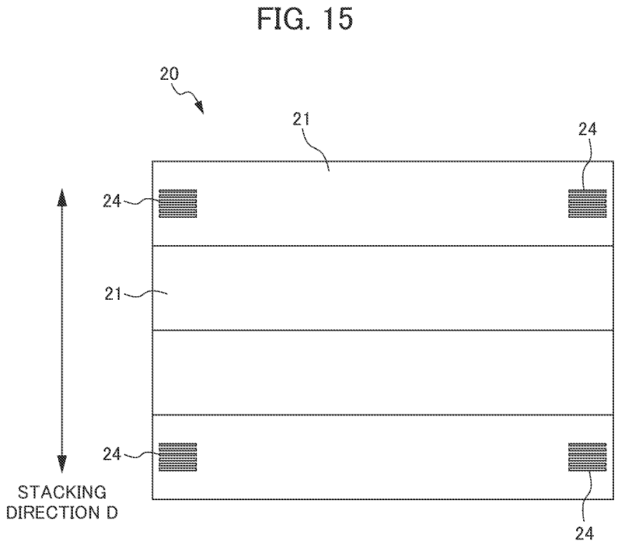

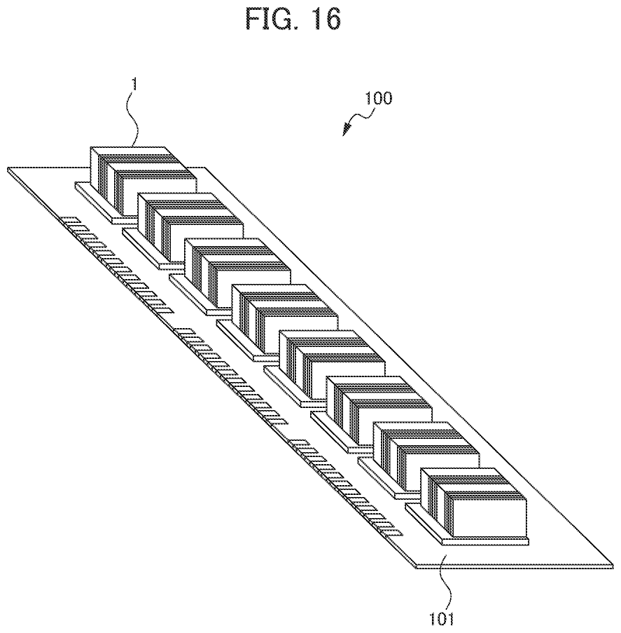

The following describes a memory unit 20, a semiconductor module 1, and manufacturing methods thereof according to an eighth embodiment of the present invention with reference to FIG. 15. In the description of the eighth embodiment, the same elements of configuration as those of the foregoing embodiments are denoted by the same reference numerals, and description thereof will be omitted or simplified. The semiconductor module according to the eighth embodiment differs from those according to the first to seventh embodiments in that protruding terminals 24 in the semiconductor module according to the eighth embodiment are disposed in predetermined positions on each of memory chips 21 located at opposite ends in the stacking direction D as shown in FIG. 15.

Each of the memory chips 21 located at the opposite ends in the stacking direction D has, on one side surface thereof, protruding terminals 24 disposed at opposite ends in a width direction. The protruding terminals 24 may be arranged to form a different shape at each of the opposite ends in the width direction. Specifically, at each of the opposite ends in the width direction, some of the protruding terminals 24 are arranged in the thickness direction of the memory chip 21 to form a predetermined shape. For example, four protruding terminals 24 are arranged in the thickness direction of The memory chip 21 to form a square shape at one end in the width direction, and four protruding terminals 24 are arranged in the thickness direction of the memory chip 21 to form a circular shape at the other end in the width direction. The arrangement of the protruding terminals 24 at one end in the stacking direction D is, for example, opposite to the arrangement of the protruding terminals 24 at the other end. The protruding terminals 24 are, for example, used as alignment marks when the memory unit 20 is placed over the memory substrate 10. The protruding terminals 24 that are used as, for example, alignment marks are not connected to other terminals.

The memory unit 20, the semiconductor module 1, and the manufacturing methods thereof according to the eighth embodiment described above produce the following effects.

(14) The protruding terminals 24 are disposed at the opposite ends in the width direction on one side surface of each of the memory chips 21 located at the opposite ends in the stacking direction D. This configuration makes it possible to easily form alignment marks, because the protruding terminals 24 are used as alignment marks. This configuration also helps increase the positioning accuracy for when the memory substrate 10 and the memory unit 20 are connected.

### Ninth Embodiment

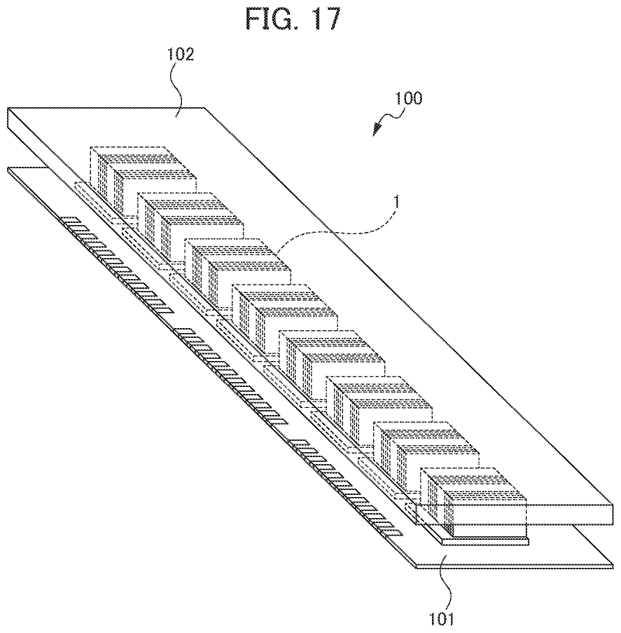

The following describes a DIMM module 100 and a manufacturing method thereof according to a ninth embodiment of the present invention with reference to FIGS. 16 and 17. The DIMM module 100 according to the ninth embodiment includes a plurality of semiconductor modules 1 according to any of the first to eighth embodiments, a DIMM board 101, and a heat spreader 102. The method for manufacturing the DIMM module 100 according to the ninth embodiment includes an arrangement step and a heat spreader placing step in addition to the steps of the manufacturing methods of the semiconductor modules 1 according to the first to eighth embodiments.

As shown in FIG. 16, the DIMM board 101 has the plurality of semiconductor modules 1 arranged over at least one surface thereof, which is an arrangement surface. According to the present embodiment, eight semiconductor modules 1 are arranged over the DIMM board 101.

As shown in FIG. 17, the heat spreader 102 is a plate-like body having an area large enough to extend across the semiconductor modules 1 arranged over the DIMM board 101. The heat spreader 102 is placed across all of the memory units 20 in the plurality of semiconductor modules 1, and in contact with either or both of the memory units 20 and the adhesive layers 40.

Next, the method for manufacturing the DIMM module 100 according to the present embodiment will be described. In the arrangement step, the plurality of semiconductor modules 1 manufactured are arranged over at least one surface, which is an arrangement surface, of the DIM board 101. In the arrangement step according to the present embodiment, the semiconductor modules 1 are arranged over one surface of the DIMM board 101 in a straight line at predetermined intervals.

Subsequently, the heat spreader placing step is performed. In the heat spreader placing step, the heat spreader 102 is placed across all of the memory units 20 in the plurality of semiconductor modules 1, and in contact with either or both of the memory units 20 and the adhesive layers 40.

Next, an example of the DIMM module 100 will be described. For example, the memory chips 21 have a chip thickness of 10 μm to 20 μm, each memory unit 20 includes a stack of four memory chips 21, the adhesive layers 40 have a thickness of 20 μm to 50 μm, and a plurality of memory units 20 bonded together have a maximum thickness of 5 mm. In this example, the number of memory units 20 that are included in. each semiconductor module 1 is 83 to 38. In other words, the number of memory chips 21 that are included in each semiconductor module 1 is 332 to 152. That is, it is possible to achieve a semiconductor module 1 having a memory capacity of 664 GB to 304 GB by using 2 GB (16 Gb) chips. The DIMM module 100, which includes eight semiconductor modules 1, can therefore achieve a memory capacity of 5312 GB to 2432 GB.

The semiconductor module 1 and the manufacturing method thereof according to the nineth embodiment described above produce the following effects.

(15) A DIMM module 100 includes: a plurality of the semiconductor modules 1 described above; a DIMM board 101 having the plurality of semiconductor modules 1 arranged over at least one surface thereof, which is an arrangement surface; and a heat spreader 102 placed across all of the memory units 20 in the plurality of semiconductor modules 1, and in contact with either or both of the memory units 20 and the adhesive layers 40. This configuration. makes it possible to achieve a high-capacity DIMM module 100. Due to the heat spreader 102 being placed in contact with either or both of the memory units 20 and the adhesive layers 40, it is possible to provide a DIMM module 100 that offers increased cooling effect.

(16) A method for manufacturing a DIMM module 100 includes: the method for manufacturing any of the above-described semiconductor modules 1; an arrangement step of arranging, on at least one surface of a DIMM board 101, a plurality of the semiconductor modules 1 manufactured, the at least one surface being an arrangement surface; and a heat spreader placing step of placing a heat spreader 102 across all of the memory units 20 in the plurality of semiconductor modules 1, and in contact with either or both of the memory units 20 and the adhesive layers 40. This method makes it possible to manufacture a high-capacity DIMM module 100 that offers increased cooling effect.

The memory units 20, the semiconductor modules 1, the DIMM module 100, and the manufacturing methods thereof according to preferred embodiments of the present invention have been described above. However, the present invention is not limited to the embodiments described above, and modifications can be made thereto as appropriate.

For example, in any of the embodiments described above, the semiconductor module 1 may include only one memory unit 20. In this case, the semiconductor module 1 does not need to have the adhesive layer 40.

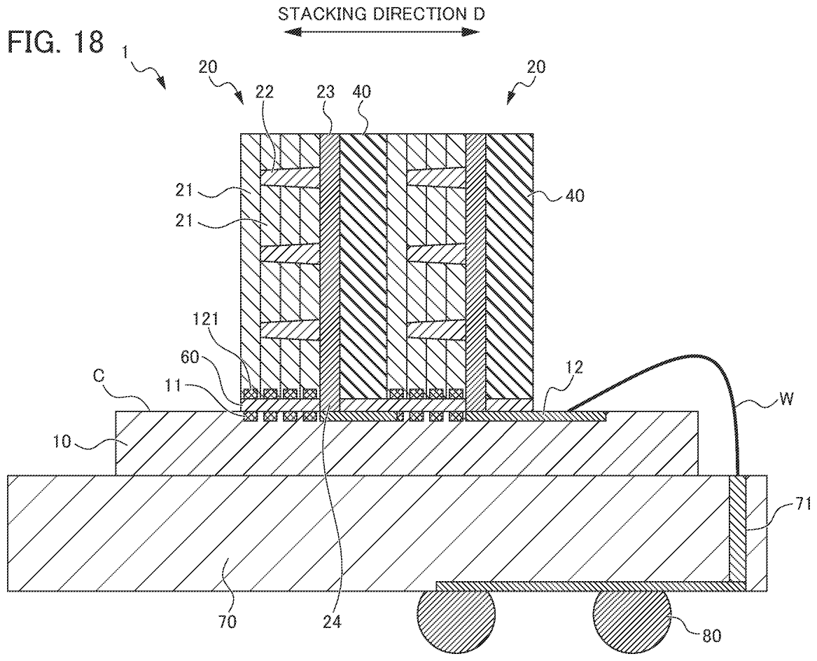

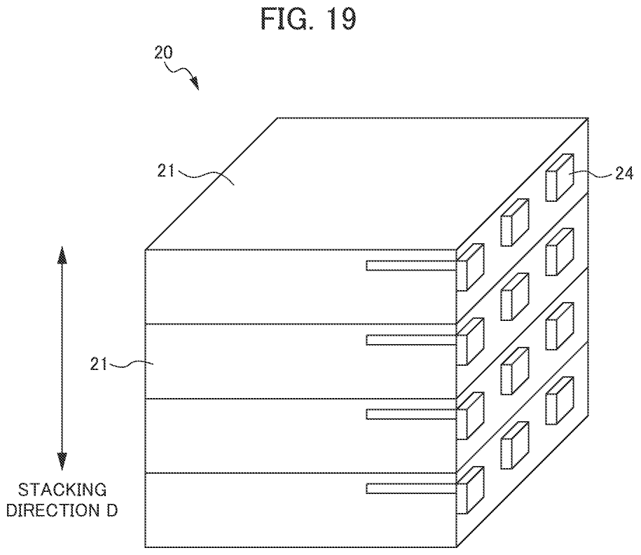

For another example, in any of the first to sixth embodiments described above, the memory substrate 10 may have, instead of the electrodes that penetrate the memory substrate 10 in the thickness direction, a power terminal 12 disposed on the placement surface C and a wire W that is used for wire bonding as shown in FIG. 18. In this configuration, the memory substrate 10 does not need to have the pillars 31. Furthermore, the semiconductor module 1 does not need to have a sealant. In this case, the memory substrate 10 and the package substrate 70 are directly connected to each other. This configuration eliminates the need for power supply electrodes that penetrate the memory substrate 10 in the thickness direction, achieving a manufacturing cost reduction.

For another example, in the first embodiment described above, the protruding terminals 24 may be bent along side surfaces of the memory chips 21 as shown in FIG. 19. This configuration allows the protruding terminals 24 to have a larger connection area, facilitating the bonding of the protruding terminals 24 and the substrate.

For another example, in. the seventh embodiment described above, the protruding terminals 24 may have coupling parts 242 as in the third and fourth embodiments. The protruding terminals 24 may have the coupling parts 242 in a configuration in which, for example, the potential at the protruding terminals 24 is the same among the stack of the memory chips 21.

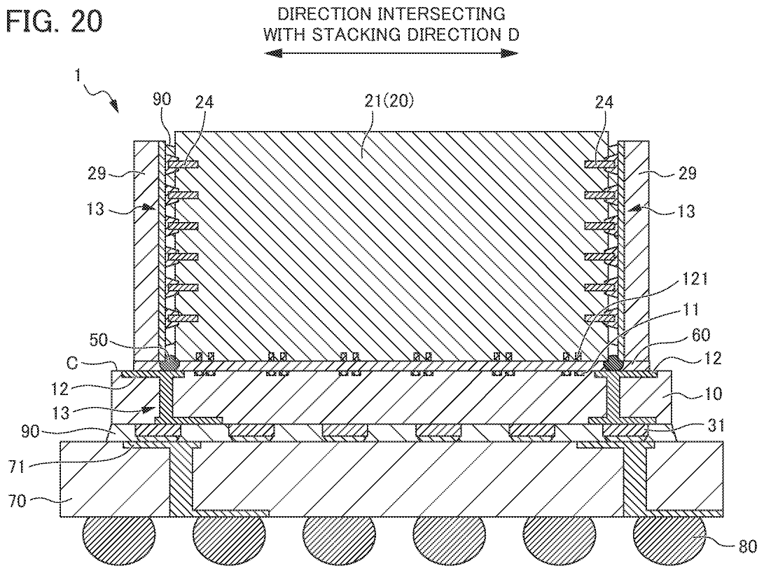

In the seventh embodiment, the protruding terminals 24 are disposed on side surfaces of the memory chips 21 and arranged along one end of each memory chip 21 in the thickness direction. Furthermore, the semiconductor module 1 includes the power supply plate 29 connected to the protruding terminals 24, and is thus connected to an external power supply circuit. In a modification thereto, as shown in FIG. 20, opposed power supply plates 29 may be respectively disposed on opposite side surfaces of a stack of memory chips 21, or a power supply plate 29 may be disposed on at least one of the side surfaces. That is, the opposed power supply plates 29 may be respectively disposed on exposed surfaces among surfaces extending in directions intersecting with the thickness direction of the memory chips 21. Furthermore, the power supply plate(s) 29 and the memory substrate 10 may be provided with a conductive path 13 for connection through a connecting part 50 and a power terminal 12. Communication between the memory chips 21 and the memory substrate 10 may be performed in a contactless manner through communication circuits 11 and communication parts 121. In this case, no connecting part 50 is present in an area where the communication circuits 11 and the communication parts 121 are located, increasing the accuracy of the positioning between the communication circuits 11 and the communication parts 121. A sealing part(s) 90 may be provided between the side surface(s) of the memory unit 20 and the power supply plate(s) 29.

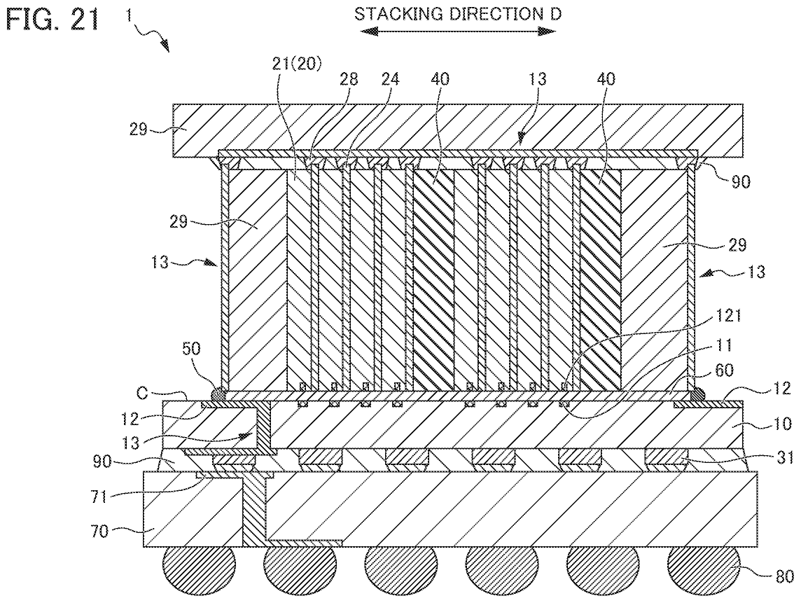

For another example, the protruding terminals 24 may protrude from an upper surface of each memory unit 20, which is a surface opposite to a surface opposed to the memory substrate 10 among the surfaces of the memory unit 20, as shown in FIG. 21. This means that the protruding terminals 24 may protrude from surfaces of the memory chips 21 that are not opposed to the placement surface of the memory substrate 10 and that are different from surfaces facing in the stacking direction among the surfaces of the memory chips 21. Then, the memory chips 21 may be respectively supplied with electric power from the protruding terminals 24. Specifically, electric power may be supplied from the protruding terminals 24 through conductive paths 13, microbumps 28, and connecting parts 50. Note here that, the conductive paths 13 are disposed on the upper surfaces of the memory units 20 and on the opposed power supply plates 29 disposed on the opposite side surfaces of the memory units 20 in the stacking direction D or the power supply plate 29 disposed on at least one of the side surfaces. That is, the power supply plates 29 are disposed on exposed surfaces of the memory units 20. The conductive paths 13 (power supply plates 29) are electrically connected to the connecting parts 50. The microbumps 28 connect the protruding terminals 24 and the conductive paths 13. Communication between the memory chips 21 and the memory substrate 10 may be performed in a contactless manner through communication circuits 11 and communication parts 121. In this case, no connecting part 50 is present in an area where the communication circuits 11 and the communication parts 121 are located, increasing the accuracy of the positioning between the communication circuits 11 and the communication parts 121. A sealing part(s) 90 may be provided between the upper surfaces of the memory units 20 and the power supply plate(s) 29.

### EXPLANATION OF REFERENCE NUMERALS

1: Semiconductor module
10: Memory substrate
11: Communication circuit
12: Power terminal
13: Conductive path
20: Memory unit
21: Memory chip
22: Through electrode
23: Electrode layer
24: Protruding terminal
25: Scribe area
27: Bonding layer

### 28: Microbump

29: Power supply plate

### 30: Bump

### 31: Pillar

40: Adhesive layer
50: Connecting part
60: Mount part
70: Package substrate
71: Package electrode
60: Solder ball
90: Sealing part
100: DIMM module
101: DIMM board
102: Heat spreader
121: Communication part
241: Base part
242: Coupling part
C: Placement surface
D: Stacking direction

1. A memory unit having a plurality of memory chips, the memory unit comprising:
the plurality of memory chips put in a stack; and
a protruding terminal disposed in the memory unit and protruding from a side surface thereof along a stacking direction,
wherein one of opposite-facing surfaces of the protruding terminal in a direction intersecting with a protruding direction thereof has a greater surface roughness than the other.

2. The memory unit according to claim 1, wherein the protruding terminal includes:
a plurality of base parts that are embedded in the memory unit and that protrude from the memory unit; and
a coupling part that extends in the stacking direction while being exposed from the side surface of the memory unit and that couples the base parts,
wherein one of opposite-facing surfaces of the coupling part in a direction intersecting with a protruding direction of the base parts has a greater surface roughness than the other.

3. The memory unit according to claim 1, wherein one of opposite-facing surfaces of the protruding terminal in a direction along the stacking direction has a greater surface roughness than the other.

4. A semiconductor module having a plurality of memory chips, the semiconductor module comprising:
a memory substrate having a power terminal exposed on one surface thereof, which is a placement surface; and
at least one memory unit placed over the placement surface of the memory substrate, the at least one memory unit being the memory unit according to claim 1,
wherein the protruding terminal protrudes from one end surface in the stacking direction and is connected to the power terminal.

5. The semiconductor module according to claim 4, comprising a pair of the memory units located adjacent to each other and further comprising an adhesive layer located adjacent to the protruding terminal in each of the memory units.

6. The semiconductor module according to claim 4, further comprising a connecting part disposed between the power terminal and one end of the protruding terminal in the protruding direction of the protruding terminal, the connecting part electrically connecting the protruding terminal and the power terminal.

7. The semiconductor module according to claim 4, wherein
the memory substrate has a communication circuit, and
the memory chips have, at one end thereof adjacent to the memory substrate, a communication part configured to communicate with the communication circuit.

8. A semiconductor module having a plurality of memory chips, the semiconductor module comprising:
the memory unit according to claim 1; and
a power supply plate connected to the protruding terminal, wherein
the memory substrate over which the memory unit is placed has a communication circuit,
the memory chips have a communication part configured to communicate with the communication circuit, and
the protruding terminal is disposed on a side surface that is different from a surface where the communication part is disposed.

9. The semiconductor module according to claim 7, further comprising a mount part through which the memory unit is mounted to the placement surface of the memory substrate, the mount part being placed on a portion of the placement surface of the memory substrate that is opposed to the memory unit and being not placed on a portion that is opposed to the protruding terminal.

10. A semiconductor module having a plurality of memory chips, the semiconductor module comprising:
a memory substrate having a communication circuit and a power terminal exposed on one surface thereof, which is a placement surface;
at least one memory unit placed over the placement surface of the memory substrate, the at least one memory unit including the plurality of memory chips put in a stack; and
a power supply plate disposed on an exposed surface of the memory unit and electrically connected to the power terminal, wherein
the memory substrate has a communication circuit,
the memory chips have, at one end thereof adjacent to the memory substrate, a communication part configured to communicate with the communication circuit in a contactless manner, and
the memory chips have a protruding terminal protruding from at least one surface that is not opposed to the placement surface of the memory substrate and that is different from surfaces facing in the stacking direction.

11. A DIMM module comprising:
a plurality of the semiconductor modules according to claim 4; and
a DIMM board having the plurality of semiconductor modules arranged over at least one surface thereof, which is an arrangement surface.

12. A DIMM module comprising:
a plurality of the semiconductor modules according to claim 4;
a DIMM board having the plurality of semiconductor modules arranged over at least one surface thereof, which is an arrangement surface; and
a heat spreader placed across all of the memory units in the plurality of semiconductor modules, and in contact with either or both of the memory units and adhesive layers.

13. A method for manufacturing a memory unit having a plurality of memory chips, the method comprising:
a memory unit formation step of forming memory units by stacking memory wafers having the plurality of memory chips, a scribe area, and protruding terminals that span the memory chips and the scribe area; and
a singulation step of performing etching on the scribe area, except for the protruding terminals therein, thereby dividing the memory wafers into the individual memory units and exposing the protruding terminals.

14. A method for manufacturing a semiconductor module, comprising:
the method according to claim 13;
a memory unit placement step of placing the memory chips with an end of the protruding terminal in an in-plane direction opposed to a power terminal; and
a connection step of electrically connecting the memory unit to a memory substrate.

15. A method for manufacturing a semiconductor module, comprising:
the method according to claim 13;
a memory unit placement step of placing the memory chips; and
a power supply plate connection step of connecting an end of the protruding terminal in an in-plane direction to a power supply plate,
wherein in the memory unit placement step, the memory unit is opposed to and disposed on a memory substrate.

16. The method for manufacturing a semiconductor module according to claim 14, further comprising:
an adhesive layer formation step of forming, before the memory unit placement step, an adhesive layer on one stacking direction-facing surface of the protruding terminal in one of the memory units for bonding another memory unit; and
a bonding step of bonding the two memory units using the adhesive layer before the memory unit placement step and after the adhesive layer formation step.

17. A method for manufacturing a DIMM module, comprising:
the method for manufacturing a semiconductor module according to claim 14; and
an arrangement step of arranging, on at least one surface of a DIMM board, a plurality of the semiconductor modules manufactured, the at least one surface being an arrangement surface.

18. A method for manufacturing a DIMM module, comprising:
the method for manufacturing a semiconductor module according to claim 14;
an arrangement step of arranging, on at least one surface of a DIMM board, a plurality of the semiconductor modules manufactured, the at least one surface being an arrangement surface; and
a heat spreader placing step of placing a heat spreader across all of the memory units in the plurality of semiconductor modules, and in contact with either or both of the memory units and adhesive layers.
